(19) United States
(12) Patent Application Publication
(10) Pub. No.: US 2025/0201532 A1
(43) Pub. Date: Jun. 19, 2025

(54) SUBSTRATE PROCESSING DEVICE AND SUBSTRATE PROCESSING METHOD

(71) Applicant: TOKYO ELECTRON LIMITED, Tokyo (JP)

(72) Inventor: Hachishiro IIZUKA, Yamanashi (JP)

(21) Appl. No.: 18/847,897

(22) PCT Filed: Mar. 17, 2023
(86) PCT No.: PCT/JP2023/010707

§ 371 Date: Sep. 17, 2024

(30) Foreign Application Priority Data
Mar. 29, 2022 (JP) 2022-054095

(51) Int. Cl. H01J 37/32; H01L 21/311

(52) U.S. Cl. CPC H01J 37/32541; H01J 37/32568; H01J 37/3255; H01J 2237/332; H01J 2237/334; H01L 21/31116

(57) ABSTRACT

There is provided an apparatus for processing a substrate, comprising: a substrate holder disposed in a processing chamber and configured to hold the substrate; a processing gas supplying part configured to supply a processing gas into the processing chamber; a surrounding member disposed to surround a peripheral portion of the substrate held by the substrate holder and having an annular wall portion made of a dielectric; a plasma actuator disposed at the wall portion and configured to plasmarize the processing gas supplied by the processing gas supply part and form flow of plasma of the processing gas along the wall portion in a preset direction; and an injection mechanism configured to inject the plasma formed by the plasma actuator and flowing along the wall portion toward the peripheral portion of the substrate held by the substrate holder to perform processing using the plasma.

### TECHNICAL FIELD

The present disclosure relates to a substrate processing apparatus and a substrate processing method.

### BACKGROUND

In a semiconductor device manufacturing process, a peripheral portion of a semiconductor wafer (hereinafter, referred to as “wafer”) that is a substrate is processed.

For example, Patent Document 1 discloses a technique in which a laser beam is irradiated to a bevel portion of a wafer held by a spin chuck, and a bevel/backside polymer is etched and removed while rotating the wafer by the spin chuck.

### PRIOR ART DOCUMENTS

### Patent Documents

Patent document 1: Japanese Laid-open Patent Publication No. 2015-233064

### SUMMARY

### Problems to Be Resolved by the Invention

The present disclosure provides a technique capable of processing a peripheral portion of a substrate using plasma.

### Means for Solving the Problems

The present disclosure is an apparatus for processing a substrate, comprising:
a substrate holder disposed in a processing chamber and configured to hold the substrate;
a processing gas supplying part configured to supply a processing gas into the processing chamber;
a surrounding member disposed to surround a peripheral portion of the substrate held by the substrate holder and having an annular wall portion made of a dielectric;
a plasma actuator disposed at the wall portion and configured to plasmarize the processing gas supplied by the processing gas supply part and form flow of plasma of the processing gas along the wall portion in a preset direction; and
an injection mechanism configured to inject the plasma formed by the plasma actuator and flowing along the wall portion toward the peripheral portion of the substrate held by the substrate holder to perform processing using the plasma,
wherein the plasma actuator includes:
an annular first electrode connected to one pole of a radio frequency (RF) power supply and disposed on a surface side of the wall portion; and
an annular second electrode connected to the other pole of the RF power supply and disposed at a position separated from the first electrode toward a downstream side in a direction in which the flow of the plasma is formed, and embedded more in the wall portion than the first electrode.

### Effect of the Invention

In accordance with the present disclosure, the peripheral portion of the substrate can be processed using plasma.

### BRIEF DESCRIPTION OF THE DRAWINGS

FIG. 1 is a longitudinal side view showing an example of a configuration of a wafer processing apparatus of the present disclosure.

FIG. 2 is an explanatory diagram showing an example of arrangement of a wafer during etching.

FIGS. 3A and 3B are explanatory diagrams showing an operation principle of a plasma actuator.

FIG. 4 is a perspective view showing an example of a configuration of a surrounding member where the plasma actuator is disposed.

FIG. 5 is a longitudinal side view showing an enlarged example of a configuration of the surrounding member.

FIG. 6 is a longitudinal side view showing an example of a configuration of the plasma actuator disposed at the surrounding member.

FIG. 7 is an enlarged longitudinal cross-sectional view showing an example of a configuration of a wall portion on which the plasma actuator is disposed.

FIG. 8 is an explanatory diagram showing a first operation example of the plasma actuator.

FIG. 9 is an explanatory diagram showing a second operation example of the plasma actuator.

FIG. 10 is an explanatory diagram showing a third operation example of the plasma actuator.

FIG. 11 is an explanatory diagram showing an operation example of a plasma actuator related to another configuration.

FIGS. 12A and 12B show test examples of dielectric barrier discharge.

### DETAILED DESCRIPTION

### <Wafer Processing Apparatus>

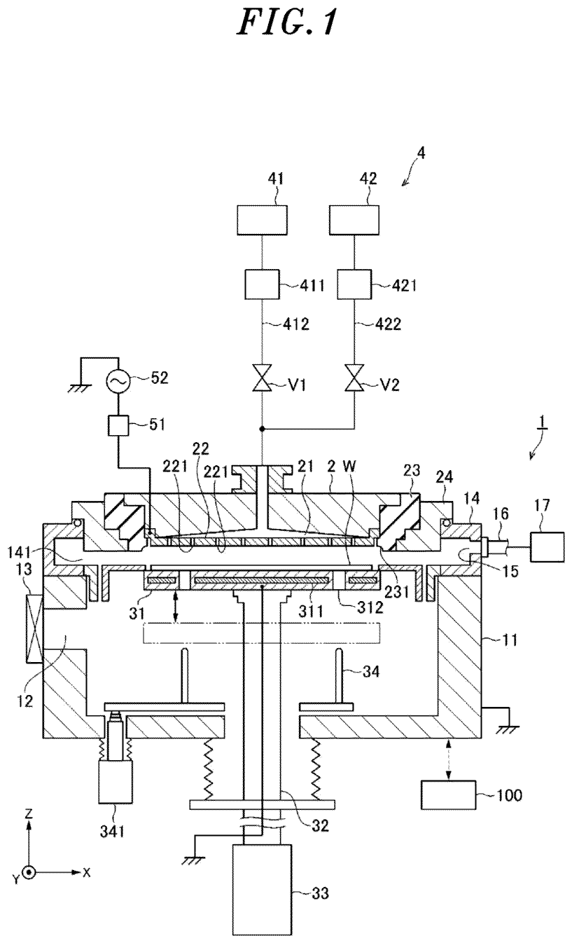

First, an example of an overall configuration of a wafer processing apparatus 1, which is an embodiment of “apparatus for processing a substrate” of the present disclosure, will be described with reference to FIG. 1. The wafer processing apparatus 1 of this example has a function of forming a film on a wafer W using a film forming gas, and a function of removing a film formed on a peripheral portion of the wafer W by plasma etching using a plasma actuator 6.

A film formed on the wafer W is not particularly limited, and it may be a metal oxide film or metal nitride film for forming an insulating film, a metal film for forming a wiring layer, or a hard mask for protecting an area that is not removed during etching.

The wafer processing apparatus 1 is configured to supply a film forming gas, such as a reactive gas or a raw material gas containing a film raw material such as a metal compound, into a processing chamber 11 where the wafer W is accommodated and processed, and form a film of a desired material on the surface of the wafer W. A method for forming a film may be a chemical vapor deposition (CVD) method in which a film forming gas is continuously supplied to deposit a film material on the surface of the wafer W. Alternatively, it may be an atomic layer deposition (ALD) method in which the supply and exhaust of a raw material gas and the supply and exhaust of a reactive gas are alternately performed, and the adsorption of the raw material gas on the wafer W and the reaction are repeated to laminate a thin film of the film material.

The processing chamber 11 in this example is made of a flat and cylindrical metal, and is grounded. A loading/unloading port 12 for transferring the wafer W and a gate valve 13 for opening and closing the loading/unloading port 12 are disposed on a sidewall of the processing chamber 11. An exhaust duct 14 having an annular shape in plan view is disposed above the loading/unloading port 12. A slit-shaped exhaust port 141 extending along a circumferential direction is formed on an inner peripheral surface of the exhaust duct 14. An opening 15 is formed on a sidewall surface of the exhaust duct 14, and one end of an exhaust line 16 is connected to the exhaust port 141 through the opening 15. An exhaust mechanism 17 including a pressure control mechanism or a vacuum pump is connected to the other end of the exhaust line 16.

A placing table 31 for horizontally placing the wafer W is disposed in the processing chamber 11. A heater 311 for heating the wafer W is disposed in the placing table 31. An upper end of a rod-shaped support member 32 that penetrates through a bottom portion of the processing chamber 11 and extends in a vertical direction is connected to a central portion of a bottom surface of the placing table 31. A lifting mechanism 33 is connected to a lower end of the support member 32, and the placing table 31 can be raised and lowered between a lower position indicated by a dashed dotted line in FIG. 1 and an upper position indicated by a solid line in FIG. 1 by the lifting mechanism 33. The lower position is a transfer position for transferring the wafer W to and from a transfer mechanism (not shown) for the wafer W which enters the processing chamber 11 from the loading/unloading port 12. The upper position is a processing position where film formation is performed on the wafer W.

Here, the lifting mechanism 33 in this example does not have a function of rotating the placing table 31 around the central axis of the support member 32.

The placing table 31 is not necessarily configured to be raised and lowered by the lifting mechanism 33, and may be fixedly disposed in the processing chamber 11. In that case, for example, the loading/unloading port 12 is disposed at a height position where the wafer W can be loaded and unloaded directly in the space above the placing table 31. On the other hand, the exhaust line 16 may be disposed on the bottom side of the processing chamber 11 so that evacuation can be performed in a downward direction via a side circumferential area of the placing table 31.

A plurality of support pins 34 configured to be raised and lowered by the lifting mechanism 341 are disposed below the placing table 31. When the placing table 31 is located at the transfer position, if the support pins 34 are raised and lowered, the support pins 34 protrude and retract from the upper surface of the placing table 31 through through-holes 312 formed in the placing table 31. Accordingly, the wafer W can be transferred between the placing table 31 and an external transfer mechanism.

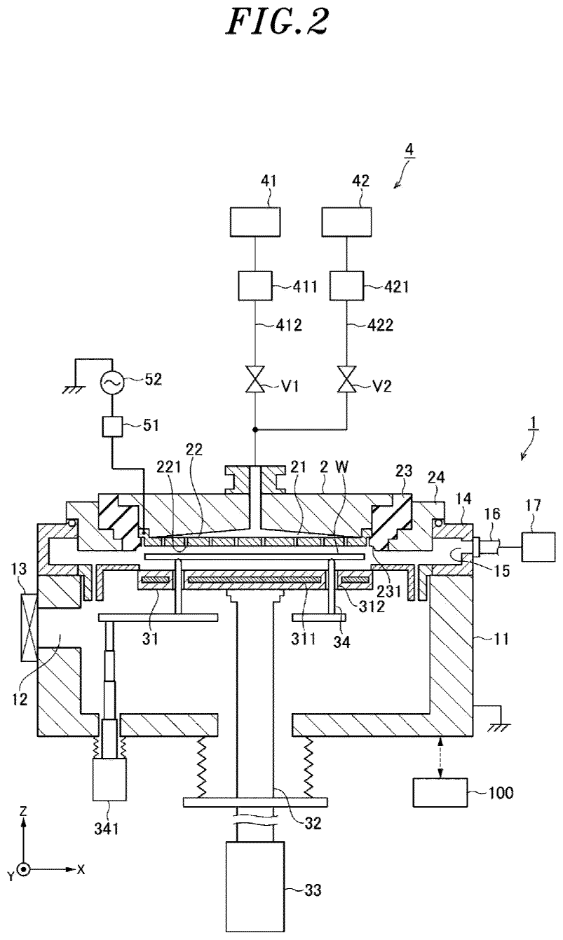

Further, in the lifting mechanism 341, a lifting movement range of the support pins 34 is set such that the support pins 34 can be raised and lowered from the upper surface of the placing table 31 even when the placing table 31 is located at the processing position. In order to remove a film on the peripheral portion of the wafer W by plasma etching with this configuration, the wafer W is lifted from the upper surface of the placing table 31 by the support pins 34 as shown in FIG. 2. Hence, plasma etching is performed in a state where the peripheral portion of the wafer W is positioned close to the plasma actuator 6 disposed at a surrounding member 23 to be described below. From this perspective, the support pins 34 correspond to a substrate holder for holding the wafer W that has been subjected to plasma etching.

### <Gas Shower Head 2 and Gas Supply System 4>

A gas shower head 2 is disposed at the inner side of the annular exhaust duct 14, i.e., above the placing table 31. A gas diffusion space 21 is formed in the gas shower head 2, and a gas distribution plate 22 having a plurality of gas supply holes 221 is disposed on the bottom surface side of the gas diffusion space 21. A film forming gas or an etching gas supplied into the gas diffusion space 21 is discharged through the gas supply holes 221 toward the wafer W placed on the placing table 31 or the wafer W held by the support pins 34.

A gas supply system 4 for supplying a film forming gas or an etching gas to the gas diffusion space 21 is connected to the gas shower head 2. The gas supply system 4 includes a film forming gas supply part 41 for supplying a film forming gas for performing film formation on the wafer W, and an etching gas supply part 42 for supplying an etching gas for plasma etching. One end of a film forming gas supply line 412 is connected to the film forming gas supply part 41, and a flow rate controller 411 and a valve V1 are interposed in that order in the film forming gas supply line 412 from the upstream side. One end of an etching gas supply line 422 is connected to the etching gas supply part 42, and a flow rate controller 421 and a valve V2 are interposed in that order in the etching gas supply line 422 from the upstream side.

The film forming gas supplied from the film forming gas supply part 41 may be a raw material gas containing a precursor (film raw material) used as a raw material for a film material of a film to be formed on the wafer W, a reactive gas that reacts with the precursor to obtain the film material, or an auxiliary gas that is added to the reactive gas to assist in converting the reactive gas into plasma.

In the case of forming a carbon film as a hard mask on the wafer W, C₂H₂, of H₂, and Ar may be used as the raw material gas, the reactive gas, and the auxiliary gas, respectively. For convenience of illustration, only one film forming gas supply part 41 is shown in FIGS. 1 and 2. However, multiple film forming gas supply parts 41 may be provided to supply the raw material gas, the reactive gas, and the auxiliary gas.

Gas species that can react with the film formed on the wafer W and remove the film using active species contained in the plasma of the etching gas are selected for the etching gas supplied from the etching gas supply part 42. As will be described later, the etching gas is locally plasmarized in a region near the peripheral portion of the wafer W to perform plasma etching of the film. Therefore, gas species that do not react with or react extremely slowly with a film even when they are brought into contact with the film in a non-plasma state are preferably used for the etching gas.

For example, when the film formed on the wafer is a carbon film, an oxidizing gas such as O₂ (N₂ and Ar as an additive gas), CO₂, or NO_{X} may be used as the etching gas. In the case of an SiO film, an SiN film, or an Si film, a fluorine-based gas such as SF₆, NF₃, CF₄, or ClF₃ may be used as the etching gas. In addition, in the case of an SiOC film and an SiC film, a mixture of a fluorine-based gas such as SF₆, NF₃, CF₄, or ClF₃ and an oxidizing gas such as O₂, CO₂, or NO_{X} may be used as the etching gas.

The etching gas corresponds to the processing gas for performing plasma processing using the plasma actuator 6. Further, the etching gas supply part 42, the flow rate controller 421, and the etching gas supply line 422 correspond to the processing gas supply part for supplying the processing gas.

For example, a purge gas supply line for supplying a purge gas that promotes discharge of the film forming gas or the etching gas from the processing chamber 11 may be joined to the gas supply lines 412 and 422. An inert gas such as argon gas or nitrogen gas may be used as the purge gas.

Further, in the case of performing film formation using plasma produced from the reactive gas or the raw material gas used as the film forming gas, the wafer processing apparatus 1 includes a plasma generation mechanism for the film forming gas. FIG. 1 shows an example in which a radio frequency (RF) power supply 52 is connected to the gas distribution plate 22 made of a metal via a matching device 51, and the placing table 31 made of a metal is grounded, thereby providing a parallel plate type plasma generation mechanism.

### <Plasma Etching Mechanism>

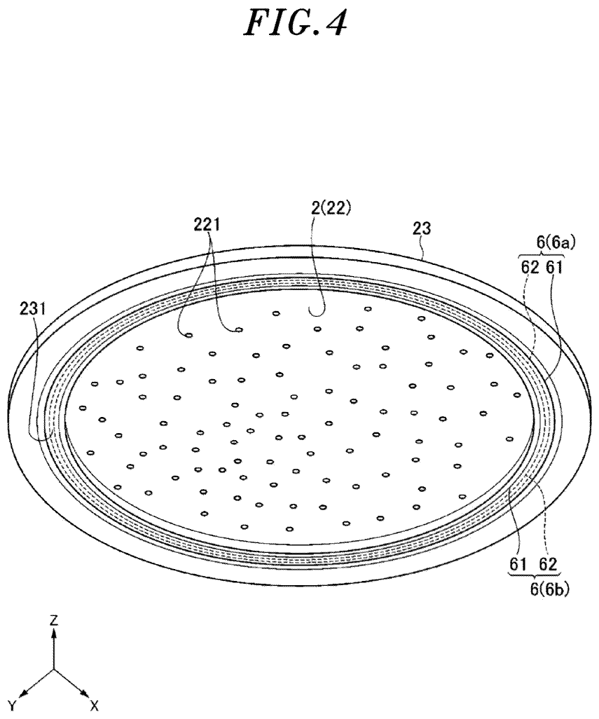

The wafer processing apparatus 1 configured as described above includes a mechanism for performing plasma processing for removing a film of a peripheral portion of the wafer W. Hereinafter, the configuration for performing the plasma processing will be described with reference to FIGS. 4 to 7.

The wafer processing apparatus 1 of the present disclosure performs the above-described plasma processing using the plasma actuator 6 for producing plasma from the etching gas as the processing gas and forming flow of plasma of the etching gas in a preset direction.

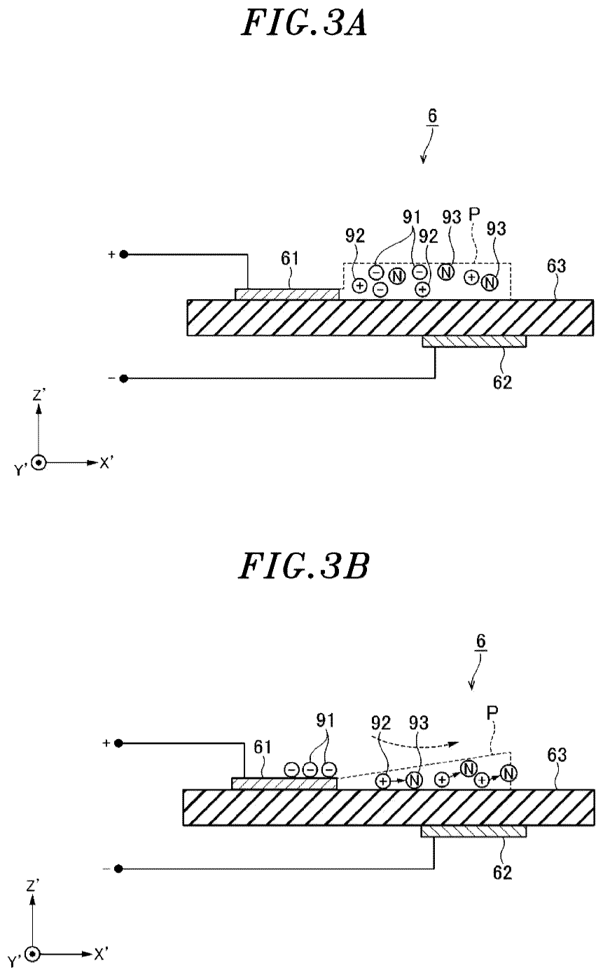

FIGS. 3A and 3B schematically show the basic configuration and the operation principle of the plasma actuator 6. The plasma actuator 6 has a configuration in which two electrodes (first electrode 61 and second electrode 62) are arranged with a dielectric 63 interposed therebetween. The processing gas is supplied to one surface (surface) on which the first electrode 61 is disposed, and the RF power is applied between the electrodes 61 and 62 to cause discharge, thereby plasmarizing the processing gas. In the plasma actuator 6, the second electrode 62 is disposed at a position separated toward a downstream side of a direction in which plasma flow is formed (X′ direction in the example shown in FIGS. 3A and 3B) when viewed from the first electrode 61.

A square-wave pulse power whose potential changes between zero and a positive potential may be applied to the plasma actuator 6 configured as described above. For example, FIGS. 3A and 3B schematically show the surface state of the dielectric 63 at the timing at which the first electrode 61 is at a positive potential. In this case, for example, dielectric barrier discharge (DBD) occurs during the period in which the first electrode 61 is at a positive potential. In DBD, the duration of discharge is short, and current pulses due to streamers appear at irregular intervals of 1 μs to 10 μs or less.

On the surface of the dielectric 63, weak ionization of the processing gas occurs during the period in which the first electrode 61 is at a positive potential, so that current pulses are generated (see FIG. 3A). In this case, electrons 91 with high mobility move to the first electrode 61, and positive ions 92 become excessive in a weakly ionized region. Further, the electrostatic force due to the electric field applied between the electrodes 61 and 62 acts on the weakly ionized region. When the positive ions 92 are subjected to the electrostatic force, they collide with neutral particles (atoms and molecules with no electric charge) 93, and energy is transferred.

The appearance of the current pulses is intermittent. Since, however, it occurs at short intervals of 1 to 10 μs or less as described above, the energy acts on the electrons 91 and the positive ions 92 substantially continuously. Therefore, a volume force (blowing force) is generated in the plasma that is bulk fluid containing the positive ions 92 or the positive ions 92. As a result, as shown in FIG. 3B, the flow of plasma P is formed from the arrangement position of the first electrode 61 toward the arrangement position of the second electrode 62.

The same applies when a rectangular wave pulse power whose potential changes between zero and a negative potential is applied. Weak ionization of the processing gas occurs at the timing at which the first electrode 61 is at a negative potential, so that current pulses are generated. Then, the electrostatic force due to the electric field applied between the electrodes 61 and 62 acts on negative ions such as oxygen. Accordingly, the negative ions collide with the neutral particles 93, and energy is transmitted. Hence, the volume force is generated, and the flow of plasma P is formed.

Also when an AC power in which the potential of the first electrode 61 changes between a positive potential and a negative potential is applied, the flow of plasma P can be formed by the same principle. For example, when current pulses are generated due to the occurrence of weak ionization of the processing gas during either the period in which the first electrode 61 is at a positive potential or the period in which the first electrode 61 is at a negative potential, the volume force based on the above-described principle is generated during the period in which the current pulses are generated to form the flow of plasma P.

In the wafer processing apparatus 1 of this example, the plasma actuator 6 is used to plasmarize the etching gas to produce plasma. The plasma is supplied to the peripheral portion of the wafer W held by the support pins 34 to remove the film on the peripheral portion. In this configuration, the wafer processing apparatus 1 include the surrounding member 23 for placing the plasma actuator 6. As shown in FIGS. 2 and 4, the surrounding member 23 of this example is formed of a dielectric member and is an annular member disposed to surround the above-described gas shower head 2 from the outer periphery of the gas shower head. The surrounding member 23 is made of a dielectric selected from a dielectric group consisting of quartz, glass, and alumina.

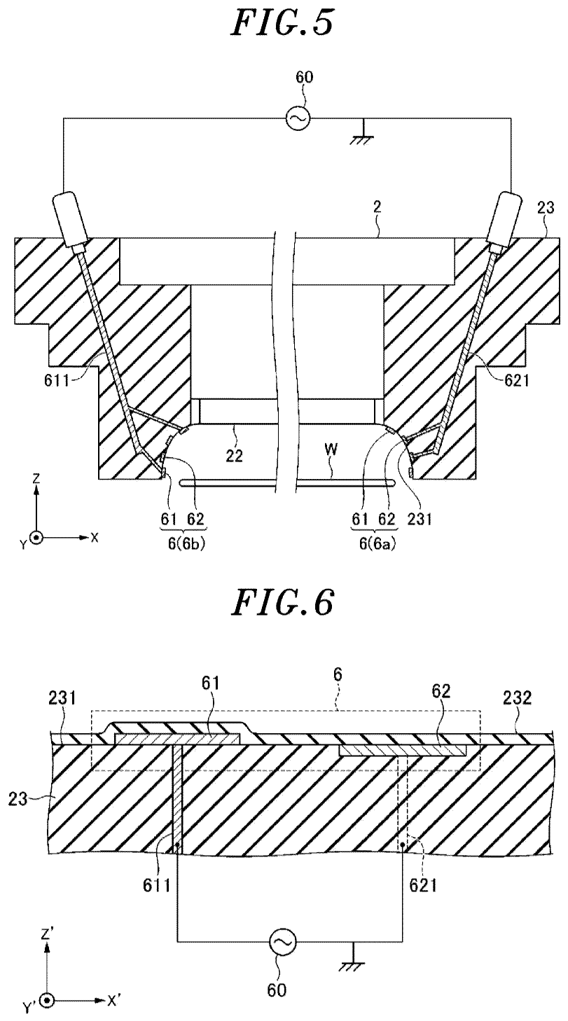

The surrounding member 23 is supported by the exhaust duct 14 via a support ring 24 that is a metal annular member, for example, and the gas shower head 2 is further supported by the surrounding member 23. Due to such arrangement, as shown in FIG. 2 or FIG. 5 to be described later, the surrounding member 23 surrounds the peripheral portion of the wafer W held by the support pins 34.

FIG. 4 is a perspective view of the gas shower head 2 (gas distribution plate 22) and the surrounding member 23 viewed from the bottom side, and FIG. 5 is an enlarged longitudinal side view of the surrounding member 23. As shown in FIGS. 4 and 5, the surrounding member 23 has a portion that protrudes downward from the bottom surface of the gas shower head 2 (gas distribution plate 22), and a wall portion 231 for installing the plasma actuator 6 is formed on the inner peripheral surface of the protruding portion. The wall portion 231 in this example has a concave surface shape in longitudinal cross sectional view, and the concave surface extends in an annular shape along the circumferential direction of the surrounding member 23.

In addition, as shown in FIGS. 2 and 5, the wall portion 231 is disposed to surround the upper region of the peripheral portion of the wafer W held by the support pins 34 from the outer peripheral side. Since the surrounding member 23 is made of a dielectric such as quartz, glass, or alumina, as described above, the wall portion 231 is also made of the dielectric.

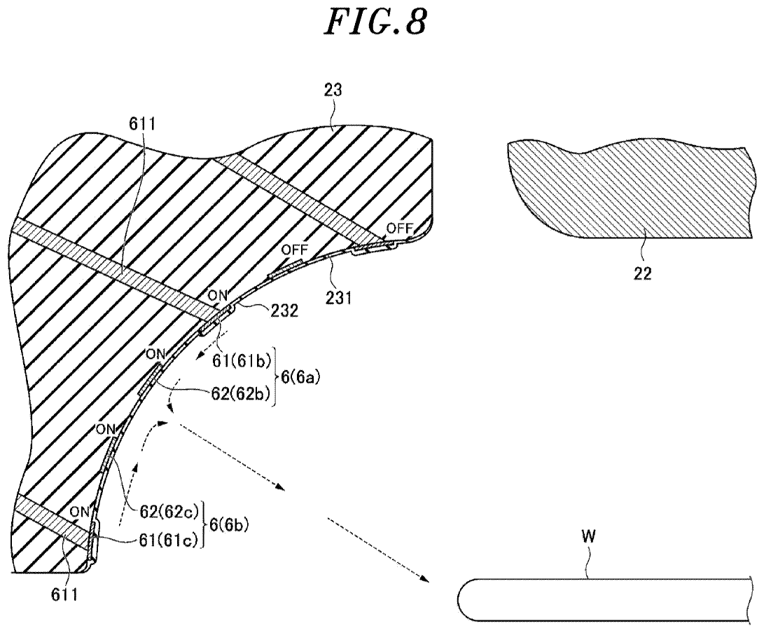

The plasma actuator 6 is formed by providing the first electrode 61 and the second electrode 62 described with reference to FIGS. 3A and 3B on the wall portion 231. Since the wall portion 231 is formed in an annular shape as described above, the first electrode 61 and the second electrode 62 in this example are also formed in the annular shape along the circumferential direction of the wall portion 231 (see FIG. 4). In FIG. 4, the first electrode 61 is indicated by a solid line, and the second electrode 62 is indicated by a dashed line. In FIG. 7 showing the arrangement of the first electrodes 61 and the second electrodes 62 in detail, and FIG. 8 to FIG. 10 showing the operations thereof, an example in which three first electrodes 61a to 61c and three second electrodes 62a to 62c are provided is illustrated. Meanwhile, for convenience of illustration, FIGS. 4 and 5 show only the first electrodes 61 and the second electrodes 62 of two pairs of the plasma actuators 6 (6a and 6b).

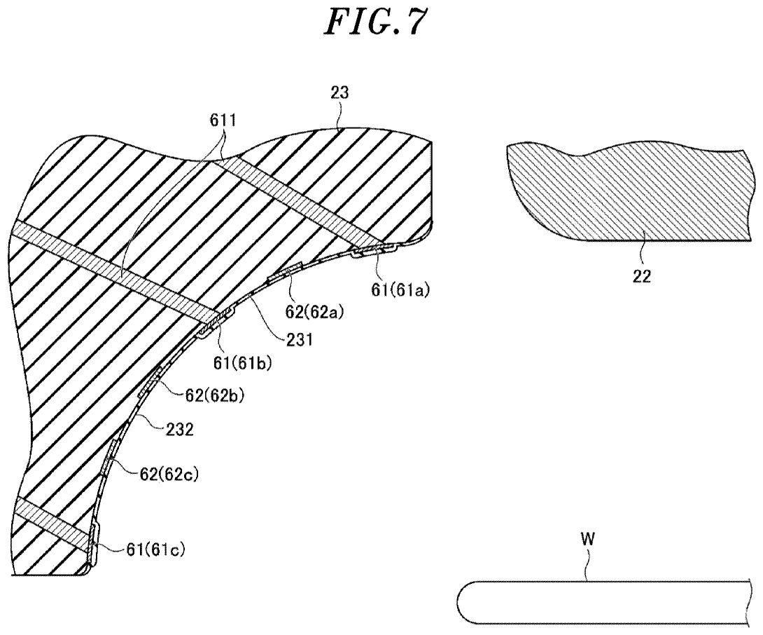

FIG. 6 is a longitudinal side view showing the configuration of the plasma actuator 6 provided on the wall portion 231. In the configuration of the plasma actuator 6, the wall portion 231 is not necessarily formed in a concave surface shape. Therefore, for convenience of explanation, FIG. 6 shows an example in which the plasma actuator 6 is provided on the wall portion 231 that is formed as a flat surface.

The first electrode 61 provided on the surface side of the wall portion 231, and the second electrode 62 disposed at a position separated from the first electrode 61 toward the downstream side of the direction in which the plasma flow (X′ direction in FIG. 6) is formed are provided on the wall portion 231 to correspond to the configuration of the plasma actuator 6 described with reference to FIGS. 3A and 3B. Further, as shown in FIG. 6, the second electrode 62 is embedded more in the wall portion 231 than the first electrode 61 formed on the surface side of the wall portion 231. As described with reference to FIG. 4, each of the first electrode 61 and the second electrode 62 is formed in an annular shape, e.g., a circular ring shape. The surfaces of the regions where the first electrode 61 and the second electrode 62 are formed and the surface of the surrounding member 23 are covered with a dielectric film 232 for protection from an etching gas.

The first electrode 61 and the second electrode 62 may be formed of a metal film such as a silver thin film or the like. In this case, on the wall portion 231 of the surrounding member 23 formed by processing a dielectric, a silver paste may be applied to the regions where the first electrode 61 and the second electrode 62 are formed. In this case, the silver paste is applied to the surface of the wall portion 231 in the region where the first electrode 61 is formed. On the other hand, in the region where the second electrode 62 is formed, the surface of the wall portion 231 is scraped to form a recess, and the silver paste is applied into the recess. Accordingly, it is possible to form the second electrode 62 that is embedded more inside the wall portion 231 than the first electrode 61.

The first electrode 61 and the second electrode 62 may be made of, in addition to silver (Ag) described above, gold (Au), copper (Cu), platinum (Pt), palladium (Pd), rhodium (Rh), iridium (Ir), ruthenium (Ru), nickel (Ni), titanium (Ti), an alloy thereof, or a conductive oxide such as indium tin oxide (ITO). The first electrode 61 and the second electrode 62 may also be formed by plating or spraying, in addition to a method of forming an electrode film by applying and baking a paste of a conductive oxide or a metal.

As shown in FIG. 6, the first electrode 61 is connected to one pole of the RF power supply 60, and the second electrode 62 is connected to the other pole of the RF power supply 60, for example, the ground terminal. An AC power or an RF pulse power with a voltage ranging from about 1 kV to 10 kV and a frequency ranging from about 1 kHz to 100 kHz is applied from the RF power supply 60. As shown in FIGS. 5 and 6, the surrounding member 23 is provided with power supply lines 611 and 621 for connecting the first electrode 61 and the second electrode 62 to the RF power supply 60, respectively. As will be described later, the wall portion 231 is provided with multiple pairs of the first electrode 61 and the second electrode 62, and the RF power supply 60 is configured to switch the first electrode 61 and the second electrode 62 to which the RF power is applied.

With the above-described configuration, the plasma actuator 6 is formed in the region of the surrounding member 23 surrounded by the dashed line in FIG. 6. Here, as described with reference to FIG. 3B, the plasma generated using the plasma actuator 6 flows along the wall portion 231. On the other hand, as shown in FIG. 2 or 5, the peripheral portion of the wafer W to be etched is separated from the wall portion 231 through which the plasma flows. Therefore, in order to supply plasma to the peripheral portion of the wafer W, it is required to change the flow direction of the plasma flowing along the wall portion 231.

Therefore, the wafer processing apparatus 1 of this example includes an injection mechanism for injecting plasma flowing along the wall portion 231 toward the peripheral portion of the wafer W held by the support pins 34 to perform processing using the plasma. In the example described with reference to FIGS. 8 to 10, a plasma injection mechanism is formed by providing multiple plasma actuators 6 (first plasma actuator 6a and second plasma actuator 6b).

The configuration example of the first plasma actuator 6a and the second plasma actuator 6b described above is illustrated in FIG. 7. Multiple pairs of the first electrode 61 and the second electrode 62 are arranged on the wall portion 231 of the surrounding member 23 shown in FIG. 7. In this example, the first electrode 61a, the second electrode 62a, the first electrode 61b, the second electrode 62b, the second electrode 62c, and the first electrode 61c are arranged in that order from the upper side toward the lower side of the wall portion 231. The method of injecting plasma using the first electrodes 61a to 61c and the second electrodes 62a to 62c will be described in accordance with the operation of the etching process.

### <Controller>

As shown in FIGS. 1 and 2, the wafer processing apparatus 1 includes a controller 100. The controller 100 is a computer including a central processing unit (CPU) and a storage part, and controls individual components of the wafer processing apparatus 1. The storage part stores a program including a group of steps (commands) for controlling the film formation on the wafer W or the etching of the peripheral portion of the wafer W. The program is stored in a storage medium such as a hard disk, a compact disk, a magneto-optical disk, a memory card, or a non-volatile memory, and is installed in the computer therefrom.

### <Film Formation>

Next, the operation of performing film formation on the wafer W and then performing plasma etching of the peripheral portion of the wafer W using the wafer processing apparatus 1 configured as described above will be described.

When the wafer W to be processed is transferred to an external vacuum transfer chamber, the gate valve 13 is opened, and a transfer mechanism (not shown) holding the wafer W is inserted into the processing chamber 11 through the loading/unloading port 12. Then, the wafer W is transferred to the placing table 31 that stands by at the lower position using the support pins 34.

Next, the transfer mechanism is retracted from the processing chamber 11, the gate valve 13 is closed to adjust the pressure in the processing chamber 11 and the temperature of the wafer W. Thereafter, the film forming gas is supplied from the film forming gas supply part 41 to the processing chamber 11 through the gas shower head 2, and the RF power is applied from the RF power supply 52 to the gas distribution plate 22 serving as an upper electrode. As a result, the film forming gas supplied to the processing chamber 11 (the space between the gas distribution plate 22 and the placing table 31) is turned into plasma due to capacitive coupling with the placing table 31 serving as a lower electrode.

In the case of performing film formation by the CVD method, the supply of the reactive gas (including the supply of an auxiliary gas; the same applies in the following description) as the film forming gas and the supply of the raw material gas may be performed at the same time. In the case of performing film formation by the ALD method, a cycle in which the supply of the raw material gas, the supply of the reactive gas, and the purging of the raw material gas or the reactive gas by the supply of a purge gas are performed in a predetermined order is repeated. In this case, the film forming gas is turned into plasma at preset timing, such as at the time of supplying the reactive gas.

After the film formation using the CVD or the ALD is performed for a preset period of time (film formation step), the supply of the film forming gas and the supply of the RF power are stopped.

### <Etching>

Next, the wafer W is lifted from the top surface of the placing table 31 by the support pins 34 and located at the position shown in FIG. 2. Then, the etching gas is supplied from the etching gas supply part 42 into the processing chamber 11 through the gas shower head 2 (processing gas supply step) and, at the same time, the RF power is applied from the RF power supply 60 between the first electrode 61 and the second electrode 62.

FIGS. 8 to 10 are explanatory diagrams of the operation of converting the etching gas into plasma using the plasma actuator 6 and supplying the plasma to the peripheral portion of the wafer W. In FIGS. 8 to 10, the first electrode 61 and the second electrode 62 to which the RF power is applied are marked with “ON”, and the first electrode 61 and the second electrode 62 to which no RF power is applied are marked with “OFF”. The RF power is applied by connecting the first electrode 61 to the RF power supply 60 and connecting the second electrode 62 to the ground terminal. On the other hand, the first electrode 61 and the second electrode 62 to which no RF power is applied are separated from the RF power supply 60 and the ground terminal.

As described in the explanation of the principle of FIGS. 3A and 3B, the plasma actuator 6 can cause DBD by applying the RF power, and form plasma flow by plasmarizing the etching gas into plasma. Therefore, the first electrode 61 and the second electrode 62 in the “OFF” state in which no RF power is applied do not operate as the plasma actuators 6. Hence, in FIGS. 8 to 10, the first electrode 61 and the second electrode 62 in the “ON” state in which the RF power is applied are referred to as “plasma actuators 6” (first plasma actuator 6a and second plasma actuator 6b).

First, in the example shown in FIG. 8, the RF power is applied between the first electrode 61b located on a third stage from the top and the second electrode 62b located on a fourth stage from the top, thereby forming the first plasma actuator 6a. Moreover, the RF power is applied to the gap between the first electrode 61c located on a sixth stage from the top and the second electrode 62c located on a fifth stage from the top, thereby forming the second plasma actuator 6b.

In the above-described first plasma actuator 6a, the second electrode 62b is disposed at a position separated toward the lower side of the wall portion 231 when viewed from the first electrode 61b. Accordingly, as indicated by dashed arrows in FIG. 8, the plasma generated by the first plasma actuator 6a flows from the first electrode 61b toward the second electrode 62b and then flows toward the lower side along the wall portion 231 (plasma flow forming step).

In the second plasma actuator 6b, the second electrode 62c is disposed at a position separated toward the upper side of the wall portion 231 when viewed the first electrode 61c. Accordingly, as indicated by dashed arrows in FIG. 8, the plasma produced by the second plasma actuator 6b flows from the first electrode 61c toward the second electrode 62c and then flows toward the upper side along the wall portion 231 (plasma flow forming step).

In this manner, the first plasma actuator 6a and the second plasma actuator 6b shown in FIG. 8 are arranged to form the plasma flow in opposing directions. When the first plasma actuator 6a and the second plasma actuator 6b are simultaneously operated, the plasma flow formed by the first plasma actuator 6a and the plasma flow formed by the second plasma actuator 6b collide with each other. Due to the collision, both plasma flows can be detached from the wall portion 231 and injected toward the peripheral portion of the wafer W. From this perspective, the first plasma actuator 6a and the second plasma actuator 6b constitute the plasma injection mechanism of this example.

When the plasma injected from the wall portion 231 reaches the peripheral portion of the wafer W, the film formed by the previous film forming process in the plasma arrival region is removed (substrate processing step). As described above, the first electrodes 61a and 61b and the second electrodes 62a and 62b are formed in an annular shape, so that the plasmas produced by the first plasma actuator 6a and the second plasma actuator 6b also have an annular shape. By causing the annular-shaped plasmas to collide with each other, the plasmas are injected from the collision position extending in an annular shape toward the peripheral portion of the wafer W. Due to such action, the etching process can be performed along the peripheral portion of the wafer W without rotating the wafer W around the vertical axis.

The arrangement locations of the first plasma actuator 6a and the second plasma actuator 6b, or the angle of the tangent direction of the concave surface of the wall portion 231 at the plasma collision location can be set by performing a reverse operation from the positional relationship between the plasma collision location and the plasma supply region on the wafer W side.

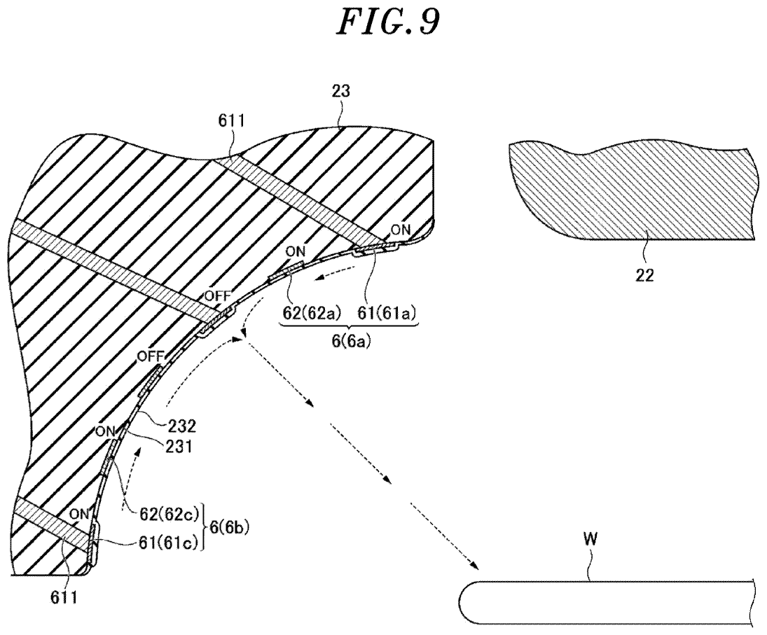

FIG. 9 shows an example of supplying plasma to a region on the upper surface side of the wafer W, compared to the example shown in FIG. 8. In this example, similarly to the example of FIG. 8, the RF power is applied between the first electrode 61c located on the sixth stage from the top and the second electrode 62c located on the fifth stage, thereby forming the second plasma actuator 6b.

On the other hand, the formation position of the first plasma actuator 6a is moved to the upper side of the wall portion 231 compared to the example of FIG. 8, and the RF power is applied to between the first electrode 61a located on the first stage from the top and the second electrode 62a located on the second stage from the top. By moving the formation position of the first plasma actuator 6a to the upper side, the position where the plasma flows formed by the first plasma actuator 6a and the second plasma actuator 6b collide is also moved to the upper side.

As described above, at least one of the plurality of first plasma actuator 6a or the plurality of second plasma actuator 6b may be provided on the common wall portion 231. In the examples shown in FIGS. 8 and 9, two first plasma actuators 6a including the first electrode 61a—the second electrode 62a and the first electrode 61b—the second electrode 62b are provided. By switching the target to which the RF power from the RF power supply 60 is applied among the plurality of plasma actuators 6 (the first plasma actuator 6a and the second plasma actuator 6b), the plasma injection position can be moved. In other words, it is possible to move the position where both plasma flows are detached from the wall portion 231 due to the collision between the plasma flow formed by the first plasma actuator 6a and the plasma flow formed by the second plasma actuator 6b.

Since the wall portion 231 has the concave surface shape in longitudinal cross section, the plasma injection direction is changed by moving the plasma injection position. In the examples shown in FIGS. 8 and 9, as the plasma injection position moves upward, the elevation angle of the plasma injection position viewed from the plasma arrival position increases. With this configuration, the peripheral region can be constantly etched while preventing the plasma arrival position from moving toward the center of the wafer W by the upward movement of the plasma injection position.

The wall portion 231 does not necessarily have a concave surface shape in longitudinal cross section. For example, if it is desired to move the etching position toward the center of the wafer W as the plasma injection position moves upward, the wall portion 231 may have an inclined surface of which inclination angle in longitudinal cross section is constant.

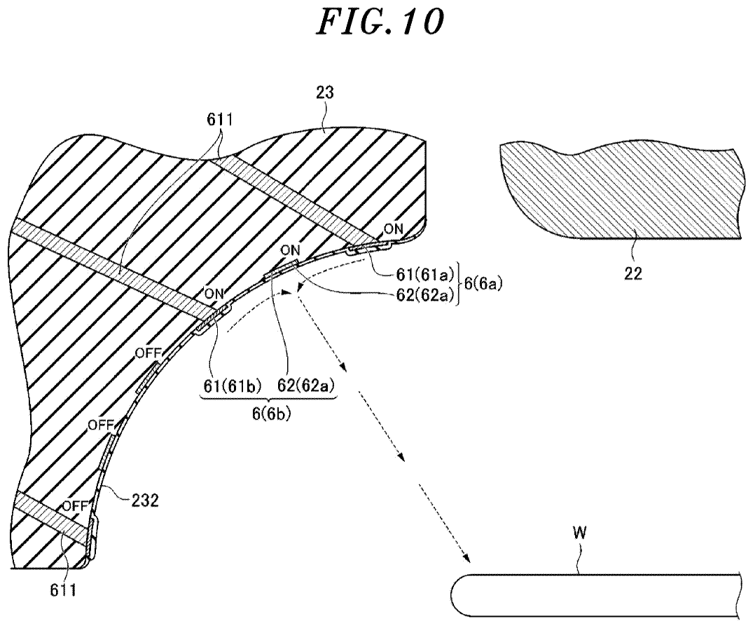

Next, in the example shown in FIG. 10, the RF power is applied to between the first electrode 61a located on the first stage from the top and the second electrode 62a located on the second stage from the top, thereby forming the first plasma actuator 6a. Further, the RF power is applied to the gap between the first electrode 61b located on the third stage from the top and the second electrode 62a located on the second stage from the top, thereby forming the second plasma actuator 6b. In other words, in this example, the second electrode 62a is common for the first plasma actuator 6a and the second plasma actuator 6b. Even when the second electrode 62a is commonly used, plasma flows can be formed in opposing directions, and the plasmas can be injected toward the peripheral portion of the wafer W due to collision.

After the plasma etching of the peripheral portion of the wafer W is performed for a preset period of time, the supply of the etching gas and the application of the RF power to the first electrode 61 and the second electrode 62 are stopped. Then, a purge gas is supplied to exhaust the etching gas remaining in the processing chamber 11, and the wafer W that has been subjected to the film formation and the plasma etching for the film on the peripheral portion is unloaded from the processing chamber 11 in the reverse order of the loading operation.

### Effects

The wafer processing apparatus 1 of the present embodiment has the following effects. The annular plasma actuator 6 is provided to surround the peripheral portion of the wafer W held by the support pins 34 to produce plasma, and the plasma is supplied to the peripheral portion of the wafer W using the injection mechanism. With this configuration, the etching can be performed along the peripheral portion of the wafer W without providing a rotation mechanism for rotating the wafer W around the vertical axis.

In the embodiment described with reference to FIGS. 8 to 10, the example, in which three or more pairs of plasma actuators 6 are provided on the wall portion 231, and the plasma injection position is moved by selecting the first plasma actuator 6a or the second plasma actuator 6b to which the RF power is supplied, has been described. On the other hand, when it is not necessary to move the plasma injection position, at least two pairs of plasma actuators 6 (the first plasma actuator 6a and the second plasma actuator 6b) for forming plasma flows in opposing directions may be provided on the wall portion 231.

### Another Embodiment

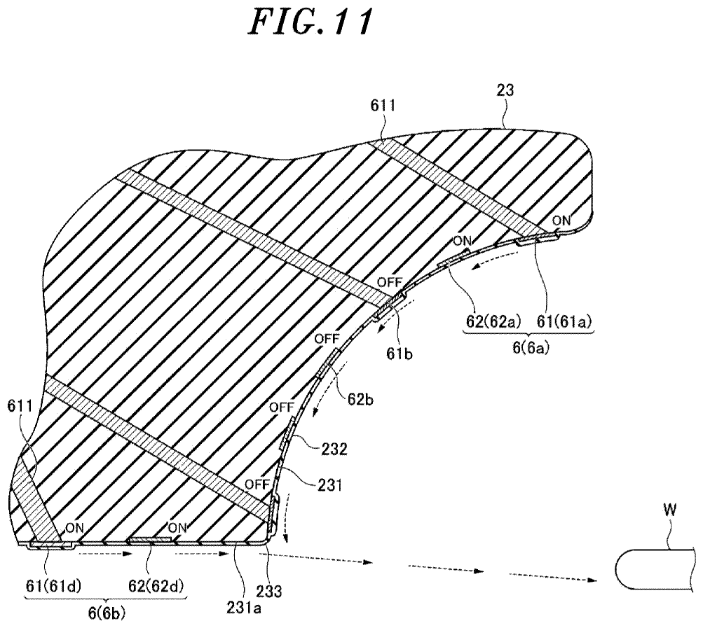

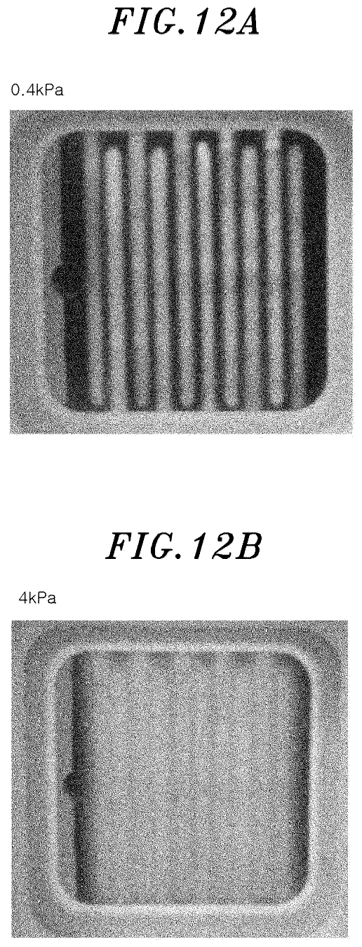

FIG. 11 shows an example in which plasma is injected toward the peripheral portion of the wafer W using an injection mechanism having a different configuration from that of the example described with reference to FIGS. 7 to 10. The surrounding member 23 of this example include a wall portion 231a formed on the bottom surface where a first electrode 61d and a second electrode 62d are disposed, in addition to the wall portion 231 formed on the inner peripheral side thereof. In the surrounding member 23 of this example, the wall portion 231a formed on the bottom surface is formed as a flat surface and surrounds the peripheral portion of the wafer W held by the support pins 34 from the outer peripheral side.

The annular first electrode 61d is disposed on the bottom surface side of the wall portion 231a described above, and the annular second electrode 62d is disposed at the inner side of the first electrode 61d. When the RF power is applied to the first electrode 61d and the second electrode 62d and the plasma actuator 6 is operated, the plasma flow is formed on the wall portion 231a from the first electrode 61d on the outer peripheral side toward the second electrode 62d on the inner peripheral side. The plasma passes through the second electrode 62d and flows further to the inner peripheral side.

On the other hand, as shown in FIG. 4, the surrounding member 23 is formed in an annular shape, and its inner circumferential surface serves as the wall portion 231, so that the wall portion 231a on the bottom surface side has an end portion 233 at the position where the wall portion 231 on the inner circumferential surface side is formed. At the end portion 233, the wall portion 231 is disconnected on the flow path when viewed from the plasma flowing along the wall portion 231a.

Due to the above configuration, the plasma that has reached the end portion 233 becomes distant from the wall portion 231a and is injected toward in a direction in which the wafer W is disposed. In this case, an injection table for injecting the plasma toward the peripheral portion can be configured by setting the tangent direction of the wall portion 231a at the end portion 233 to direct the peripheral portion of the wafer W held by the support pins 34.

As shown in FIG. 11, the plasma flow from the first plasma actuator 6a provided on the inner wall portion 231 and the plasma flow from the second plasma actuator 6b provided on the lower wall portion 231 may collide with each other. Due to the collision between the plasmas at the end portion 233, the angle of plasma injected from the injection table can be adjusted.

In the example shown in FIG. 11, the plasma flow is formed by applying the RF power to the first plasma actuator 6a (the first electrode 61a and the second electrode 62a) that is most distant from the end portion 233, thereby reducing the volume force of the plasma at the time of reaching the end portion 233. Due to such adjustment, the force when the plasma collides with the plasma flowing along the wall portion 231a on the bottom surface side is reduced, thereby suppressing the change in the plasma injection angle.

On the other hand, when it is desired to considerably change the plasma injection angle, it is preferable to form the plasma flow by applying the RF power to the first electrode 61b and the second electrode 62b that are close to the end portion 233.

On the other hand, it is not necessary to provide the plasma actuators 6 on both the wall portion 231a on the bottom surface side and the wall portion 231 on the inner peripheral surface side of the surrounding member 23. In the example shown in FIG. 11, plasma can be injected from the end portion 233 toward the peripheral portion of the wafer W by providing at least one pair of plasma actuators 6 only on the wall portion 231a on the bottom surface side. Instead of the wall portion 231a on the bottom surface side, the wall portion 231 on the inner peripheral surface side may be set such that the tangential direction at the end portion 233 faces the peripheral portion of the wafer W. In this case, at least one pair of plasma actuators 6 for producing plasma flowing toward the end portion 233 may be provided at the surrounding member 23.

### Modification

Here, the plasma actuator 6 is not necessarily configured to cause dielectric barrier discharge. For example, the plasma actuator 6 configured to cause sliding discharge may be provided on the surface side of the wall portion 231 by placing a sliding electrode with an discharge gap at the downstream side of the first electrode 61a along the plasma flow direction.

FIG. 4 illustrates an example in which the annular first electrode 61 and the annular second electrode 62 are formed of electrode wires that are connected and extend in the circumferential direction. The annular first electrode 61 or the annular second electrode 62 may be formed of a plurality of arc-shaped electrode wires arranged in an annular shape while being spaced apart from each other.

In the example described with reference to FIGS. 1 and 2, the wafer processing apparatus 1 capable of performing film formation on the wafer W and etching of the peripheral portion of the wafer W in the common processing chamber 11 has been described. However, it is not necessary that one wafer processing apparatus 1 is configured to perform both film formation and etching. For example, the wafer processing apparatus 1 may be configured to perform only etching of the peripheral portion of the wafer W. In this case, the devices such as the film forming gas supply part 41, the film forming gas supply line 412, and the flow rate controller 411 described in FIG. 2 may not be installed.

Further, the plasma processing performed on the peripheral portion of the wafer W using the plasma formed by the plasma actuator 6 is not limited to etching. For example, the film formation for forming a film on the peripheral portion of the wafer W using plasma generated from a film forming gas may be performed. The modification for modifying the surface of the peripheral portion of the wafer W using plasma generated from a modification gas may be performed.

In addition, in the case of performing plasma processing on the peripheral portion of the wafer W using the plasma produced by the plasma actuator 6, it is not necessary that the wafer W is stationary. If necessary, a rotation mechanism for rotating the wafer W around the vertical axis may be provided, and the plasma may be supplied from the plasma actuator 6 while rotating the wafer W.

It should be noted that the embodiments of the present disclosure are illustrative in all respects and are not restrictive. The above-described embodiments may be omitted, replaced, or changed in various forms without departing from the scope of the appended claims and the gist thereof.

### <Dielectric Barrier Discharge Test>

As a basic test for constructing the plasma actuator 6 illustrated in FIG. 7, a test for checking dielectric barrier discharge was executed. The electrodes (corresponding to the first electrode 61 and the second electrode 62) were arranged in a comb shape with a line width of 1 mm and an interval of 1 mm on the surface of an alumina ceramic base corresponding to the surrounding member 23. A glass paste was baked on the surface to form a dielectric film 232. The base was placed in a discharge chamber, and an AC power (rectangular waves) of 1 kV and 20 kHz was applied to between the electrodes. The discharge test was executed while setting an inner atmosphere of the discharge chamber to a mixed gas atmosphere of 5% xenon and 95% neon under different pressure conditions of 0.4 kPa (3 Torr) and 4 kPa (30 Torr).

The dielectric barrier discharge was observed under all conditions. According to comparison between the discharge states under different pressures in the discharge chamber, the spread of discharge was observed around the electrode under a low pressure atmosphere (0.4 kPa). On the other hand, the discharge state in which the electrode shape was visible through the dielectric film was observed under a high pressure atmosphere (4 kPa).

### DESCRIPTION OF REFERENCE NUMERALS

W: wafer
1: wafer processing device
23: surrounding member
231: wall portion
32: support member
42: etching gas supply part
6: plasma actuator
6a: first plasma actuator
6b: second plasma actuator
60: RF power supply
61, 61a to 61d: first electrode
62, 62a to 62d: second electrode

1. An apparatus for processing a substrate, comprising:
a substrate holder disposed in a processing chamber and configured to hold the substrate;
a processing gas supplying part configured to supply a processing gas into the processing chamber;
a surrounding member disposed to surround a peripheral portion of the substrate held by the substrate holder and having an annular wall portion made of a dielectric;
a plasma actuator disposed at the annular wall portion and configured to plasmarize the processing gas supplied by the processing gas supplying part and form flow of plasma of the processing gas along the annular wall portion in a preset direction; and
an injection mechanism configured to inject the plasma formed by the plasma actuator and flowing along the annular wall portion toward the peripheral portion of the substrate held by the substrate holder to perform processing using the plasma,
wherein the plasma actuator includes:
an annular first electrode connected to one pole of a radio frequency (RF) power supply and disposed on a surface side of the annular wall portion; and
an annular second electrode connected to the other pole of the RF power supply and disposed at a position separated from the annular first electrode toward a downstream side in a direction in which the flow of the plasma is formed, and embedded more in the annular wall portion than the annular first electrode.

2. The apparatus of claim 1, wherein the injection mechanism includes a first plasma actuator and a second plasma actuator, which serve as the plasma actuator disposed to form the flow of the plasma in opposing directions, and
the plasma flow is detached from the annular wall portion and the plasma is injected, by colliding the plasma flow formed by the first plasma actuator and the plasma flow formed by the second plasma actuator with each other.

3. The apparatus of claim 2, wherein the annular second electrode is commonly used for the first plasma actuator and the second plasma actuator.

4. The apparatus of claim 2, wherein at least one of the first plasma actuator and the second plasma actuator is plural in number, and an injection position of the plasma is moved by switching a plasma actuator to which the RF power from the RF power supply is supplied among a plurality of plasma actuators.

5. The apparatus of claim 4, wherein the annular wall portion has a concave surface shape in longitudinal cross section, so that an injection direction of the plasma is changed by moving the injection position.

6. The apparatus of claim 1, wherein the annular wall portion has an end portion where the annular wall portion is disconnected on a flow path of the plasma, and
the injection mechanism is configured as an injection table in which a tangent direction of the annular wall portion at the end portion is directed toward the peripheral portion of the substrate held by the substrate holder.

7. The apparatus of claim 1, wherein the annular first electrode and the annular second electrode are formed of a silver thin film.

8. The apparatus of claim 1, wherein the annular wall portion is made of a dielectric selected from a dielectric group consisting of quartz, glass, and alumina.

9. The apparatus of claim 1, wherein the processing gas is an etching gas for etching a film formed on a peripheral portion of the substrate.

10. The apparatus of claim 9, further comprising:
a film forming gas supply part configured to supply a film forming gas for forming a film on the substrate into the processing chamber,
wherein the etching gas is an etching gas for etching a film formed by the film forming gas.

11. A method for processing a substrate, comprising:
supplying a processing gas into a processing chamber where the substrate is held;
plasmarizing a processing gas supplied into the processing chamber using a plasma actuator, disposed at a surrounding member disposed to surround a peripheral portion of the substrate held in the processing chamber and having an annular wall portion made of a dielectric, and forming plasma flow of the processing gas along an annular wall portion in a preset direction; and
injecting the plasma formed by the plasma actuator and flowing along the annular wall portion toward the peripheral portion of the substrate held in the processing chamber to process the substrate using the plasma,
wherein in said forming the plasma flow, the plasma actuator including an annular first electrode and an annular second electrode is used, the annular first electrode is connected to one pole of an RF power supply and disposed on a surface side of the annular wall portion, and the annular second electrode is connected to the other pole of the RF power supply and disposed at a position separated from the annular first electrode toward a downstream side in which the flow of the plasma is formed and embedded more in the annular wall portion than the annular first electrode.

12. The method of claim 11, wherein the processing gas is an etching gas for etching a film formed on a peripheral portion of the substrate.

13. The method of claim 12, further comprising, before said supplying the processing gas, forming a film on the substrate by supplying a film forming gas into the processing chamber where the substrate is held,
wherein the etching gas is an etching gas for etching a film formed in said forming the film.
